(19) United States
(12) Patent Application Publication
(10) Pub. No.: US 2026/0291096 A1
(43) Pub. Date: Sep. 24, 2026

(54) Modular Automation System

(71) Applicant: Siemens Aktiengesellschaft, Muenchen (DE)

(72) Inventors: Simon WEIGL, Amberg (DE); Frantisek ZUREK, Chemnitz (DE); Andreas TRAUB, Amberg (DE); Christian AUERSWALD, Chemnitz (DE); Stefan DAUSEND, Nürnberg (DE)

(21) Appl. No.: 19/572,971

(22) Filed: Mar. 20, 2026

(30) Foreign Application Priority Data
Mar. 21, 2025 (EP) 25165202

(51) Int. Cl. H01R 12/71; H01R 25/14; H01R 31/06

(52) U.S. Cl. CPC H01R 12/716; H01R 25/142; H01R 31/06

(57) ABSTRACT

A modular automation system in which a bus connector is displaceably disposed in a bus connector space and the bus connector includes a left-hand plug, a right-hand plug, and a backplane bus plug disposed toward a module carrier, wherein the backplane bus plug is configured to receive a mating module backplane bus plug of an electronic module, where the module carriers can be arranged side-by-side to configure the automation system, and where a bus connector of a preceding module carrier is connectable to a bus connector of a succeeding module carrier by leftward displacement of the bus connector of the succeeding module carrier, thereby forming a backplane bus for the modularly configurable automation.

### BACKGROUND OF THE INVENTION

### 1. Field of the Invention

The present invention relates to a modular automation system and, more particularly, to a system for distributing I/O signals of a control system via a circuit board, where the system is typically used in industrial automation applications requiring a flexible and efficient connection between control units and various sensors and actuators.

### 2. Description of the Related Art

In automation engineering, for control systems and decentralized peripheral solutions, required actuators/sensors are connected via input/output modules to the inputs and outputs via terminals. In the case of series-produced machines or larger quantities of identical configurations or configuration variants, this results in a significant overhead in terms of labor and testing. In such cases, it is preferable for the signals not to be tapped off at the terminals of the control device, but instead to be connected via connectors and, for example, preassembled cables. For this purpose, however, the control system must output or receive the signals directly to or from a customer-specific or application-specific circuit board. The circuit board in turn has interfaces or connectors for the application-specific automation use case.

The publication “Design Guide for EJ Backplane for TwinSAFE Modules” dated Jan. 29, 2018, version 1.5.1, has already proposed a solution for application-specific configurations of modules and connectors on a circuit board.

U.S. Pub. No. 2004/201972 A1 discloses a modular automation system comprising a main unit with a bus connector, a plurality of modules each having a bus connector, and a backplane bus circuit board having a multilayer structure with bus conductor tracks, which is connected to a plurality of module connectors in which the bus connectors of the modules are disposed, where a main board is provided upon which a plurality of module connectors are disposed, and where the backplane bus circuit board is disposed in the main board, the modules being configured to communicate with the main unit via the bus connectors by means of the backplane bus circuit board, where the bus conductor tracks and the multilayer structure of the backplane bus circuit board are configured such that a layer stack comprises the bus conductor tracks and core material.

A disadvantage of conventional modular automation systems is that the layout, i.e., the routing, of a backplane bus of the mounted modules must be repeatedly created anew and checked for fault safety by the module manufacturer.

### SUMMARY OF THE INVENTION

It is an object of the present invention to provide a modular automation system that overcomes the disadvantages of conventional systems. In particular, the system is intended to ensure a more efficient distribution of I/O signals, reduce installation effort, and at the same time ensure a high degree of flexibility and compatibility with existing components.

This and other objects and advantages are achieved in accordance with the invention by a modular automation system comprising a circuit board upon which a plurality of connection elements and signal connectors are disposed. The connection elements are configured to connect to process signal cables and are connected to the signal connectors via conductor tracks of the circuit board.

An essential feature of the invention is the module carrier, which accommodates an electronic module. The module carrier has a bus connector space and a signal connector space. A movable bus connector is disposed in the bus connector space and comprises a left-hand plug, a right-hand plug, and a backplane bus plug disposed toward the module carrier.

By arranging a plurality of module carriers side-by-side, the automation system can be configured to be modular. In this process, the bus connector of a succeeding module carrier is connected to the bus connector of the preceding module carrier by displacing it to the left, thereby forming a continuous backplane bus.

This solution offers several advantages:
Reduced installation time:
By using preassembled cables and connectors, the wiring effort is significantly reduced.
Flexibility:
The system allows simple expansion and adaptation by adding or removing module carriers.
Compatibility:
Existing electronic modules can continue to be used, which reduces integration costs.
Simplified certification:
Since the backplane bus is implemented using certified components, the certification process for customer-specific configurations is simplified.

Efficient signal distribution: The direct connection of the I/O signals via the circuit board optimizes signal routing and reduces potential sources of error.

The system in accordance with the invention can be further improved by various additional features, which include, for example, the use of a bus circuit board in the bus connector, the integration of an adapter module for connection to a main unit, and the implementation of a termination module comprising a termination network and a memory component for node identification.

In order to connect a main unit, an adapter module is disposed between the main unit and a first module carrier, where the adapter module comprises an adapter circuit board upon which an adapter main unit connector and an adapter bus connector are disposed in an offset manner relative to one another. The main unit in particular is disposed on a DIN rail. As a result, a height difference between the connectors can thus be compensated.

The connection of the main unit to the module carriers and thus to the electronic modules is implemented via the adapter module, which compensates for the height difference between the connectors of the main unit mounted on a DIN rail and the module carrier slots mounted on the circuit board. The adapter module is mounted in the first slot, and the backplane bus plug of the first slot is displaced to the left in order to connect the bus to the adapter. The main unit is then displaced to the right on the DIN rail and connected to the connector in the adapter module.

The termination module performs the following functions:
Backplane bus termination:
The module contains a termination network for the backplane bus, which improves signal integrity in the system and prevents reflections at the end of the bus.
Node identification:
It includes a memory component for node identification, which facilitates configuration and management of the overall system. The termination module always identifies itself as the last module.
Modular integration:
As part of the modular system, it can be easily added or removed, which increases the flexibility of the overall configuration.
Protection and shielding:
By being disposed in a termination module carrier with a termination cover, the module is protected and may also be electrically shielded.
System termination:
It forms a defined termination of the modular configuration, which can be advantageous both electrically and mechanically.
Possible additional functions:
Depending on the specific implementation, the module may perform additional functions such as diagnostics or system monitoring.

These advantages contribute to the overall efficiency, reliability, and flexibility of the modular automation system.

The modular automation system may include empty slots, i.e., module carriers in which no electronic module is inserted, for example, for future expansions or options. The module carriers themselves cannot be directly detected by a CPU or the main unit. Only the inserted electronic modules can be polled. This means that an empty slot without an electronic module cannot be polled. Empty slots located between populated slots can be detected indirectly. For example, if slot No. 5 responds when polled, No. 6 does not, No. 7 does not, but No. 8 does respond, it can be assumed that slots Nos. 6 and 7 are present, because otherwise No. 8 could not respond, whereas the electronic modules are either defective or not present. However, optional slots are often located at the end of an assembly. Accordingly, they cannot be detected in this way. This is where the termination module provides assistance. Due to its configuratoin, it is definitively the last bus node. Nothing further can be connected to the right of the termination module. Its address is by definition the last slot in the system. After the termination module, there is nothing else. Configuration data can be stored in a memory component.

The lateral backplane bus connection can be covered by the termination module carrier, the latter providing touch protection. A passive resistor network together with a bus ASIC constitute the bus connection.

In a particularly advantageous embodiment, the module carrier has a special fastener that allows simple and secure mounting on the circuit board. These fasteners include movable actuators having latching hooks that engage in recesses of the circuit board and thus ensure reliable fixation.

The solution described creates a highly flexible, modular automation system that combines the advantages of a backplane solution with compatibility with existing modules. This enables users to achieve efficient and cost-effective integration into their automation environments while at the same time reducing installation and maintenance overhead.

Other objects and features of the present invention will become apparent from the following detailed description considered in conjunction with the accompanying drawings. It is to be understood, however, that the drawings are designed solely for purposes of illustration and not as a definition of the limits of the invention, for which reference should be made to the appended claims. It should be further understood that the drawings are not necessarily drawn to scale and that, unless otherwise indicated, they are merely intended to conceptually illustrate the structures and procedures described herein.

### BRIEF DESCRIPTION OF THE DRAWINGS

The drawings show an exemplary embodiment of the invention, in which:

FIG. 1 shows a perspective view of a module carrier from a left-hand side in accordance with the invention;

FIG. 2 shows a perspective view of the module carrier of FIG. 1 from a right-hand side;

FIG. 3 shows an exploded view of the module carrier in accordance with the invention;

FIG. 4 shows a sectional view through a guide element and an actuating element in accordance with the invention;

FIG. 5 shows an actuating element in accordance with the invention;

FIG. 6 shows a bus connector in accordance with the invention;

FIG. 7 shows the module carrier of FIG. 1 viewed from the mounting side;

FIG. 8 shows a perspective view of a module carrier with an electronic module inserted in accordance with the invention;

FIG. 9 shows a modular automation system on a circuit board in accordance with the invention;

FIG. 10 shows another perspective view of the module carrier with an electronic module inserted in accordance with the invention;

FIG. 11 shows an adapter module in accordance with the invention;

FIG. 12 shows an exploded view of the adapter module of FIG. 11;

FIG. 13 shows a termination module in accordance with the invention;

FIG. 14 illustrates the leftward displacement of the bus connector in accordance with the invention;

FIG. 15 shows a termination module carrier in accordance with the invention;

FIG. 16 shows a representation of the adapter module in accordance with the invention; and

FIG. 17 shows a representation of the signal connector space in accordance with the invention.

### DETAILED DESCRIPTION OF THE EXEMPLARY EMBODIMENTS

The following components are shown in the figures for constructing a modular automation system:

A circuit board LP, which forms the basis of the system and provides the electrical connection between the components.

Connection elements B1, B2, B3, B4, which are used to connect process signal cables and are disposed on the circuit board LP.

Signal connectors SS, SS1, SS2, which receive the module connectors of the electronic modules and are connected to the connection elements via conductor tracks.

A module carrier BC, which receives the electronic module EM and allows modular expansion of the system.

An electronic module EM, which contains the actual electronics for the automation functions.

A bus connector BS, which comprises a left-hand plug LBS, a right-hand plug RBS, and a backplane bus plug RWS. It establishes the connection between the module carriers and forms the backplane bus.

A main unit IM, which controls and coordinates the entire automation system.

An adapter module AM, which connects the main unit to the first module carrier and enables height matching.

A termination module ASM, which comprises a termination network AN for the backplane bus and a memory component Mem for node identification.

Together, the foregoing components form a flexible, modular automation system that is readily expandable and adaptable to different requirements.

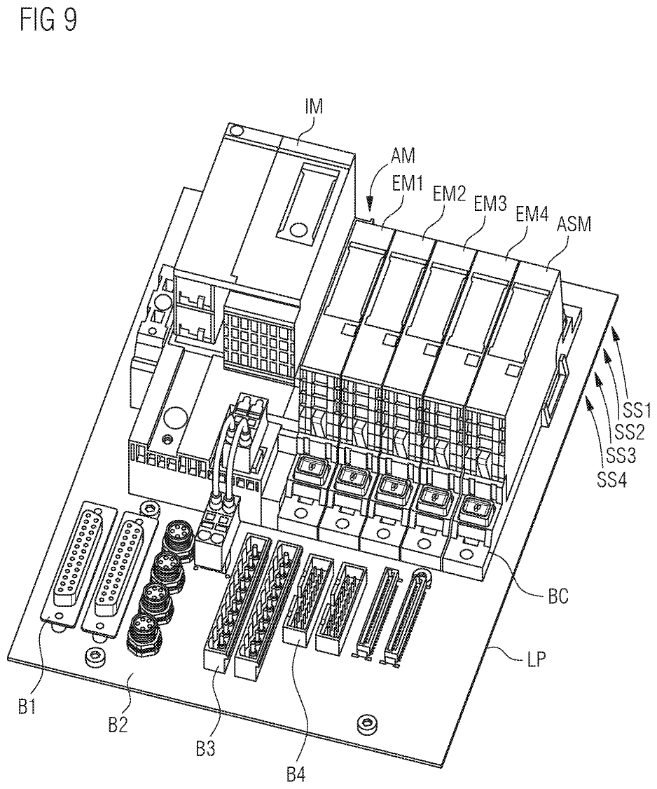

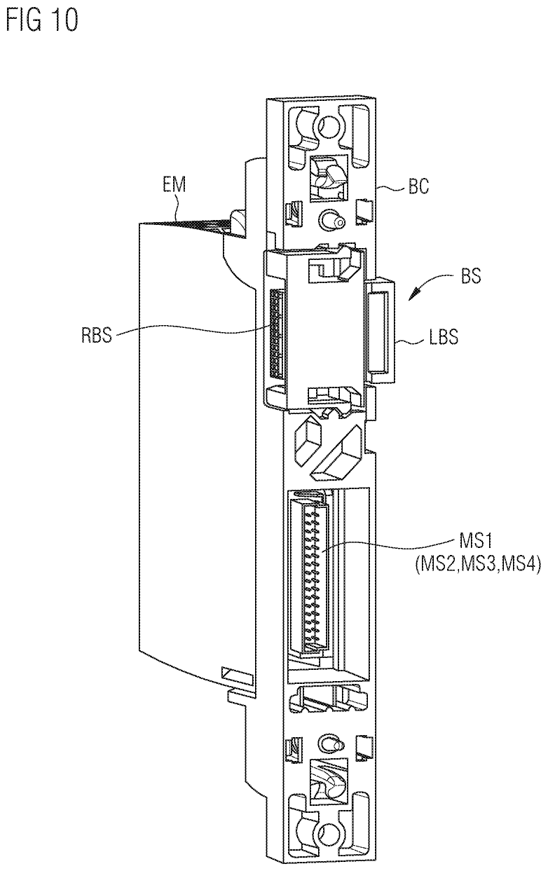

FIG. 9 shows a modular automation system 1 of the type used in process automation. A plurality of connection elements B1, B2, B3, B4 are disposed on a circuit board LP. The connection elements B1, B2, B3, B4 are connected via conductor tracks of the circuit board LP to a plurality of signal connectors SS, i.e., a first signal connector SS1, a second signal connector SS2, a third signal connector SS3, and a fourth signal connector SS4.

FIG. 17 shows a detailed partial view of the circuit board LP and of the first signal connector SS1 and the second signal connector SS2. Around the first signal connector SS1 is a cut-out portion of a module carrier BC with the corresponding signal connector space SSR. The signal connectors SS, SS1, . . . , SS4 serve to receive module connectors MS1, . . . , MS4 of the respective electronic modules EM. Disposed in the respective module carriers BC are a first electronic module EM1, a second electronic module EM2, a third electronic module EM3, and a fourth electronic module EM4. To the right of the fourth electronic module EM4, a termination module ASM forms the termination of the electronic modules EM.

The module carriers BC receive the electronic modules EM1, . . . , EM4. An adapter module AM is disposed between a main unit IM and the first electronic module EM1. The adapter module AM provides a connection between the main unit IM and the first electronic module EM1. The electronic modules EM1, . . . , EM4 are disposed on the circuit board LP via the module carriers BC and the main unit IM is disposed on a DIN rail HS. As a result, the adapter module AM is configured to offset the height difference and to establish an electrical bus connection between the main unit IM and the electronic modules EM1, . . . , EM4.

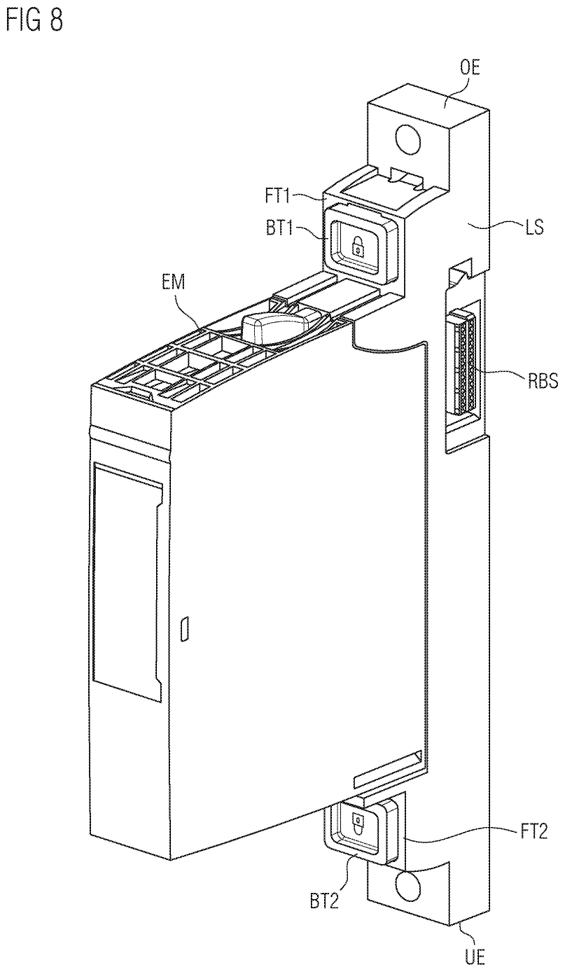

Similarly to FIG. 8, FIG. 10 shows an electronic module EM inserted into a module carrier BC, but viewed from an underside. The electronic module EM has a module connector MS1 that is seated in the signal connector space SSR. When the module carrier BC is mounted on the circuit board LP, the module connector MS1 can make electrical contact with the corresponding signal connector SS1 on the circuit board LP.

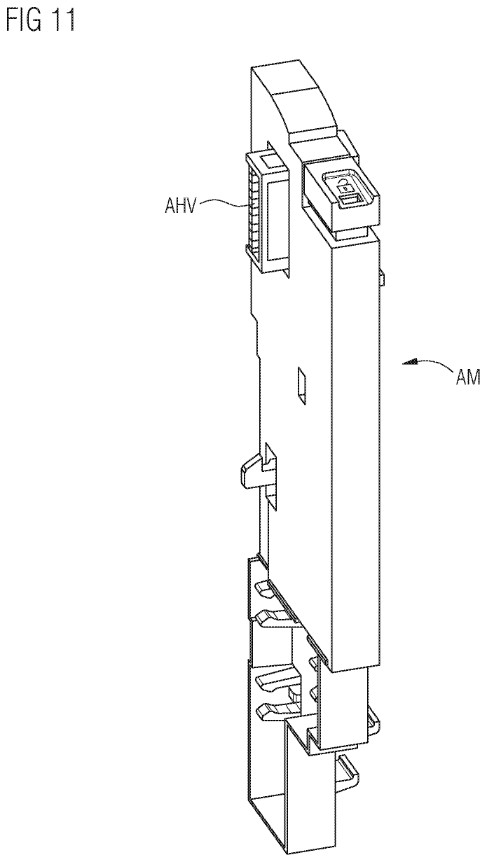

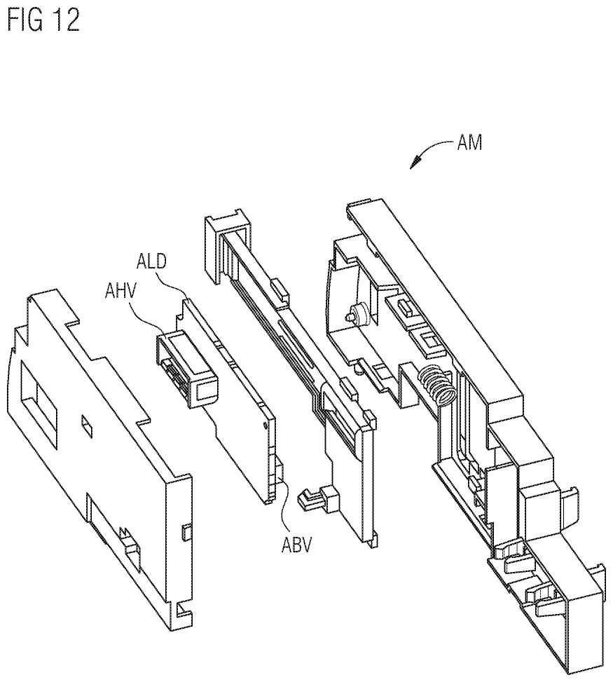

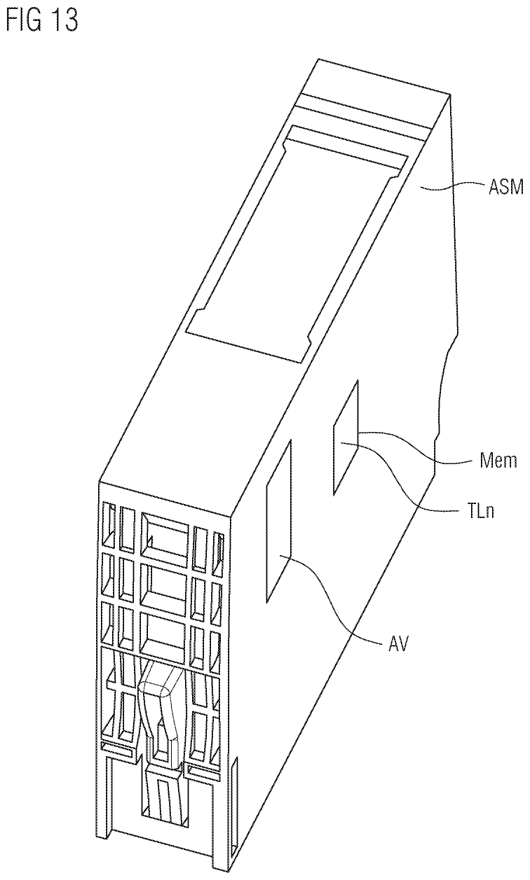

FIG. 11 shows the adapter module AM in a perspective view. The main unit IM is disposed on a DIN rail HS. As a result, the adapter module AM forms a connection between the bus connector BS of the first module carrier BC and a plug of the main unit IM. The adapter module AM comprises an adapter circuit board ALP (see FIG. 12) and an adapter main unit connector AHV.

FIG. 12 shows an exploded view of the adapter module AM. An adapter main unit connector AHV and an adapter bus connector ABV are disposed on the adapter circuit board ALP in an offset manner relative to one another to compensate for the height difference between the module carrier BC and the main unit IM.

FIG. 13 shows the termination module ASM. The termination module ASM likewise has, in its housing, a circuit board upon which a termination network AN for the backplane bus is disposed, and the circuit board of the termination module ASM additionally contains a memory component Mem for node identification. When the automation system 1 is parameterized, the memory component Mem of the termination module ASM is always assigned the node ID TIn=last node.

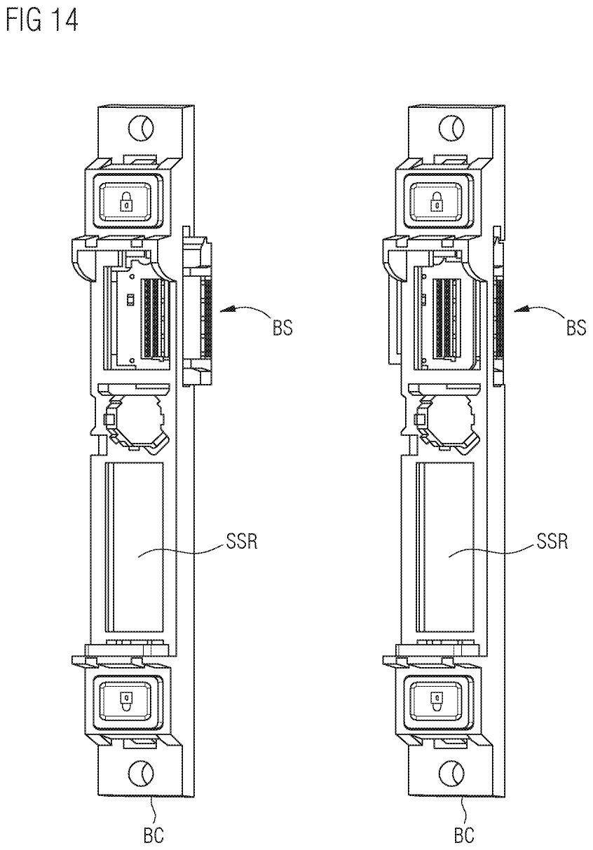

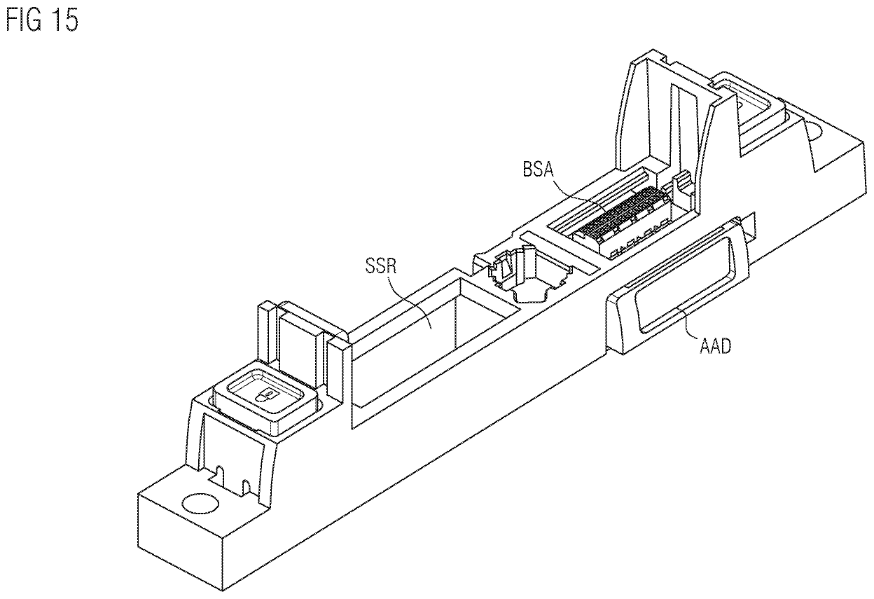

FIG. 14 further illustrates the leftward displacement of the bus connector BS to produce a continuous backplane bus RWB. Two module carriers BC are shown side-by-side. In the left module carrier BC, the bus connector BS has not yet been displaced to the left. The right module carrier BC shows the leftward-displaced bus connector BS which, when module carriers BC are disposed side-by-side, can latch into the bus connector BS of the preceding module carrier BC, where this leftward displacement of the bus connector BS of the preceding module carrier BC creates the backplane bus RWB.

In FIG. 15, a termination module carrier ABC is shown specifically for the termination module ASM. Like the other module carriers BC, the termination module carrier ABC has a signal connector space SSR. The special feature of the termination module carrier ABC is that its bus connector BS comprises only a left-hand plug LBS and a bus connector termination BSA. In addition, a termination cover AAD is provided to protect the backplane bus from contamination and from electrical contact.

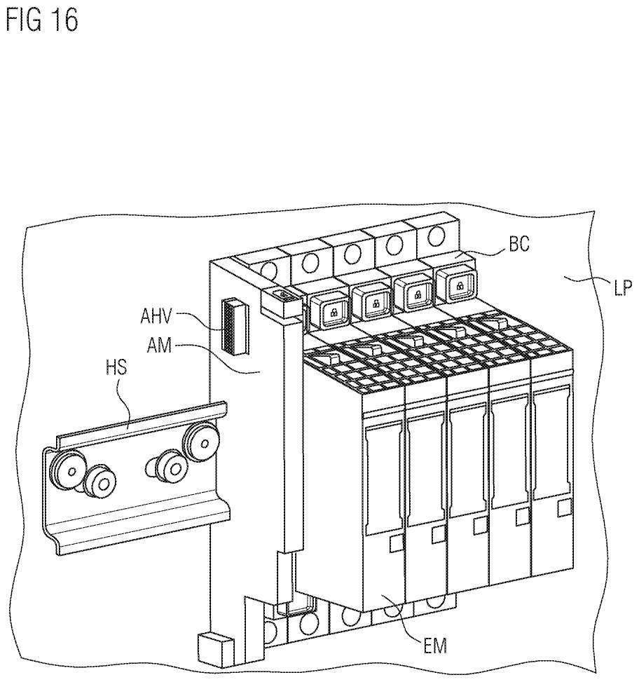

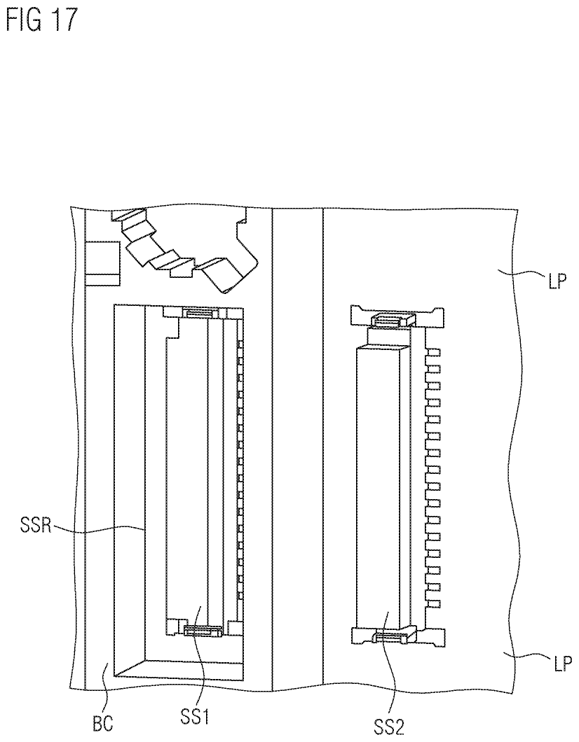

FIG. 16 further illustrates the arrangement of the DIN rail HS on the circuit board LP in conjunction with the arrangement of the module carriers BC on the circuit board LP. When a main unit IM is snapped onto the DIN rail HS and displaced to the right, the bus-connector connection of the main unit IM can latch into the adapter main unit connector AHV of the adapter module AM.

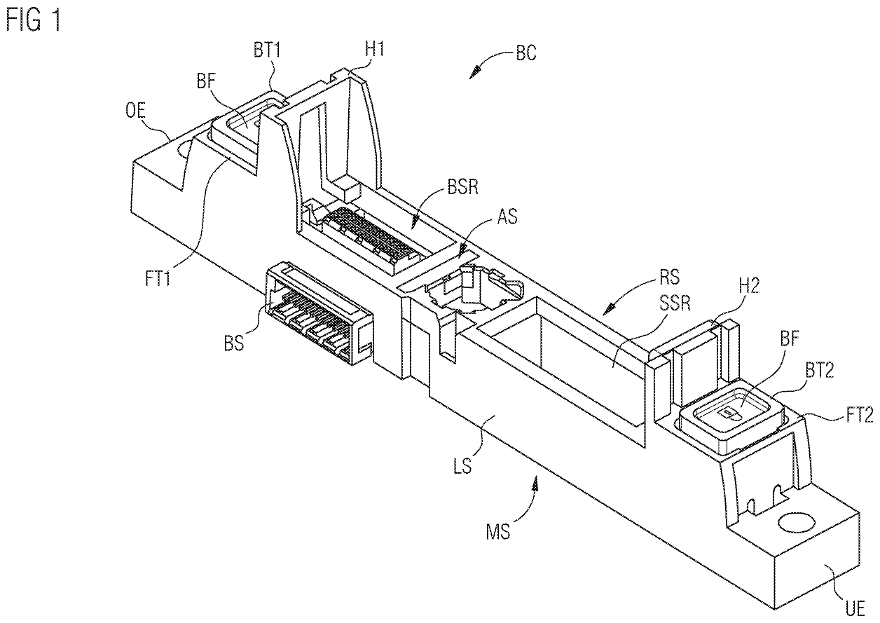

FIG. 1 shows a perspective view of a module carrier BC from a left-hand side LS of the module carrier BC. The module carrier BC serves to subsequently receive an electronic module EM. For this purpose, the module carrier BC comprises a mounting side MS, configured to mount on a mounting plate MP, the left-hand side LS, a right-hand side RS, and a receiving side AS for the electronic module EM, where the receiving side AS is opposite to the mounting side MS. The module carrier BC also has an upper end OE and a lower end UE. For fastening to a mounting plate, the upper end OE and the lower end UE each have a through-hole. For faster and simpler fastening on the mounting plate MP, the module carrier BC additionally comprises, in the region of the upper end OE, a first fastener BT1 and, in the region of the lower end UE, a second fastener BT2.

The first fastener BT1 and the second fastener BT2 are configured such that in each case an actuator BT1, BT2 is movably disposed in a respective guide element FT1, FT2. The guide element FT1, FT2 is configured such that the actuating element BT1, BT2 can be displaced from the receiving side AS toward the mounting side MS by an installer applying pressure to a control surface BF.

If a mounting plate MP, such as a multilayer circuit board, already has a latching hole at the corresponding location, then the module carrier BC can be rapidly fastened to the circuit board via the actuator BT1, BT2, each of which has a latching hook RH.

The latching hook RH is elastically deformable such that, in a first position S1 of the actuator BT1, BT2, it already exerts a spring force inside the guide element FT1, FT2.

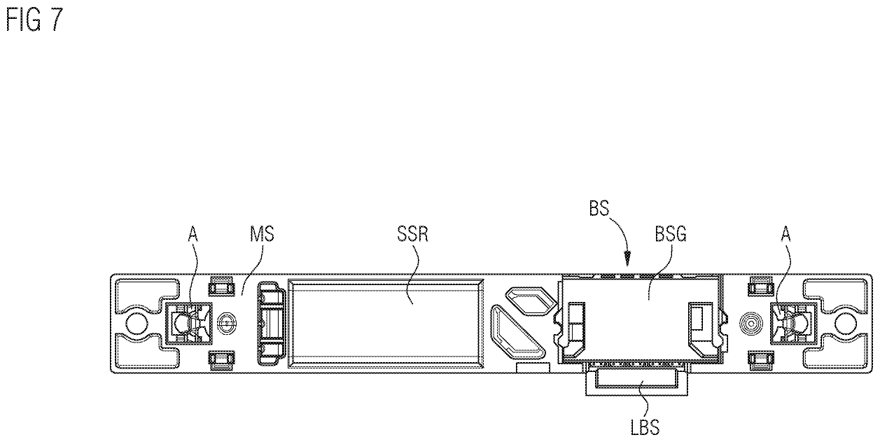

The guide element FT1, FT2 has a recess A in the mounting side MS (see FIG. 7). As a result, the latching hook RH, in a second position S2 of the actuator BT1, BT2, can go past the recess A with its latching nose RN and penetrate into, or pass through, an opening O of the mounting plate MP. The latching hook RH is elastically deformable. Consequently, latching hook RH will now spring out of the circuit board or out of the mounting plate MP with its latching nose RN and latch behind the mounting plate MP.

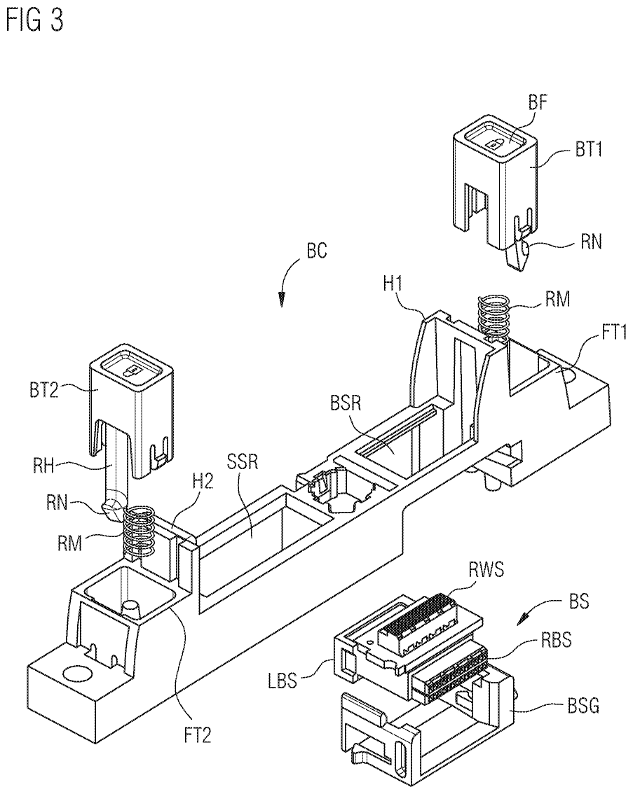

Within the guide element FT1, FT2, a return element RM is disposed between the mounting side MS and the actuator BT1, BT2 (see also FIGS. 3, 4, and 5). In these examples, the return element RM is formed as a coil spring. The coil spring is disposed between the actuator BT1, BT2 and the guide element FT1, FT2. As a result, it presses the actuator BT1, BT2 back toward the receiving side AS when an installer ceases to apply pressure to the control surface BF. The actuator BT1, BT2 can then remain in a locking position SV such that the latching nose RN presses against the mounting plate MP. This securely fixes the module carrier BC on the mounting plate MP.

To hold an electronic module EM securely, the module carrier BC has a first retaining means H1 and a second retainor H2.

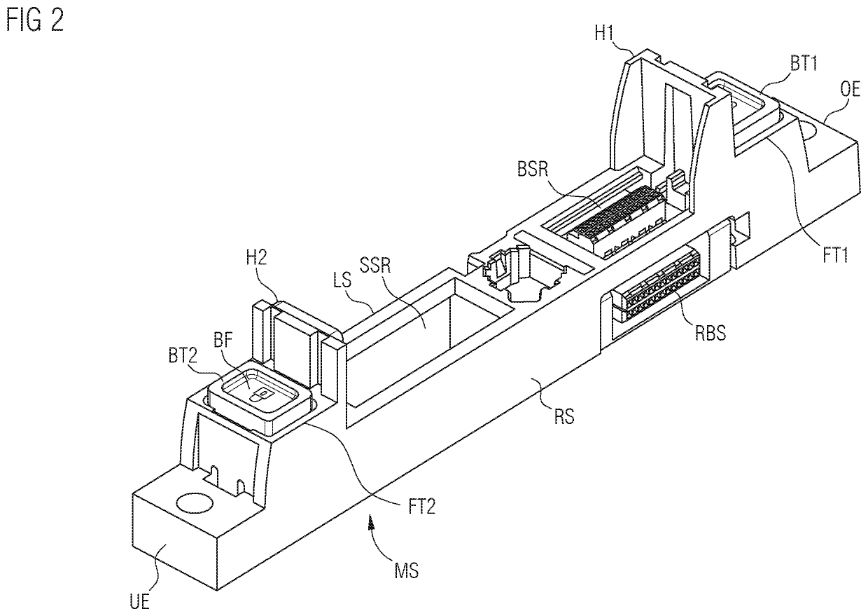

In FIG. 2, the module carrier BC already known from FIG. 1 is shown in another perspective view from its right-hand side RS. As already illustrated in FIG. 1, the module carrier BC has a bus connector space BSR and a signal connector space SSR. A bus connector BS is disposed in the bus connector space BSR, and the signal connector space SSR is recessed into the mounting side MS so that, in the mounted state, space is provided for a signal connector located on the mounting plate MP.

The module carrier BC as shown in FIG. 1 or FIG. 2 is configured such that a modular automation system can be assembled by arranging a plurality of module carriers BC side-by-side. The bus connectors BS are configured to be displaceable, and an internal backplane bus can thus be formed for a plurality of module carriers BC via the bus connectors BS.

FIG. 3 again illustrates, in an exploded view of the module carrier BC, the mounting positions of the actuators BT1, BT2 and of the guide elements FT1, FT2, and in particular the displaceable mounting of the bus connector BS.

The bus connector BS is in turn embedded in a bus connector housing BSG. The bus connector space BSR within the module carrier BC and the bus connector BS are configured such that the bus connector BS, together with its bus connector housing BSG, is displaceable within the bus connector space BSR. The bus connector BS comprises a left-hand plug LBS disposed toward the left-hand side LS, a right-hand plug RBS disposed toward the right-hand side RS, and a backplane bus plug RWS disposed toward the receiving side AS.

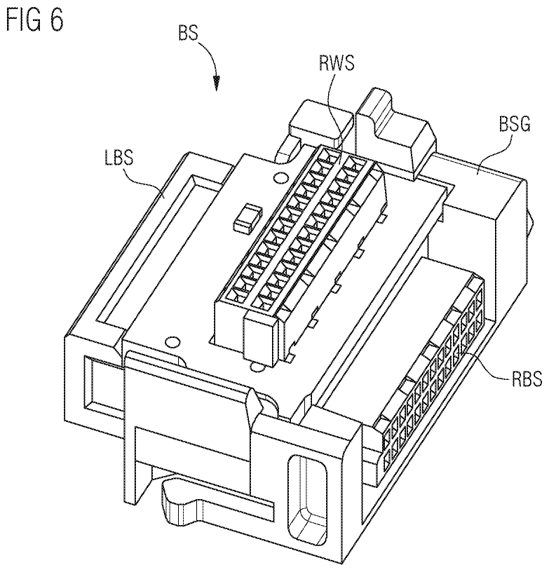

The technical effect of the displaceably disposed bus connector housing BSG can now be explained with reference to FIG. 6. In the event of a leftward displacement, the bus connector housing BSG is configured to latch into the correspondingly formed bus connector space BSR, such that the left-hand plug LBS is engaged with a respective right-hand plug RBS of a bus connector BS of a preceding module carrier, and such that the backplane bus plug RWS is located in a central position, so that an electronic module EM insertable via the receiving side AS is in contact with the backplane bus plug RWS via a mating backplane bus plug GRS.

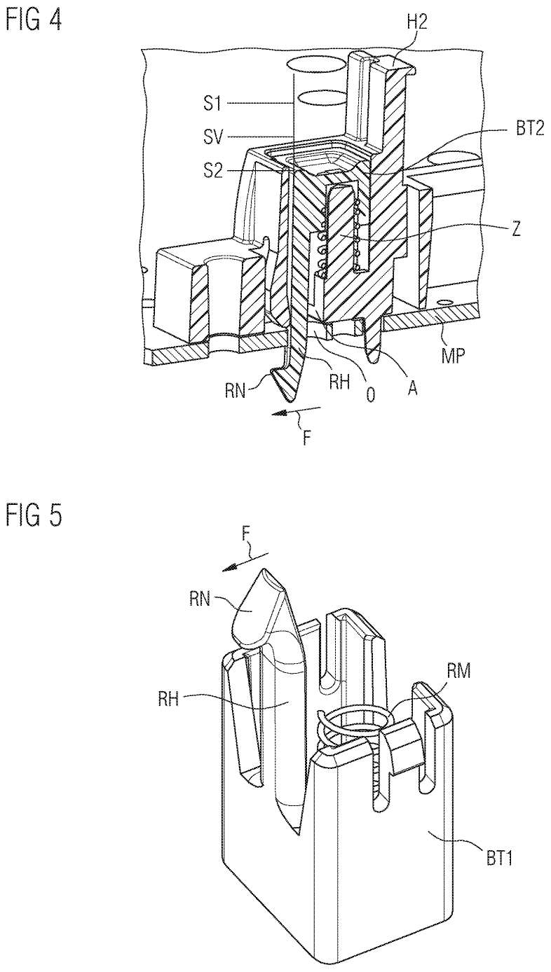

FIG. 4 shows a sectional view through the module carrier BC of the second guide element FT2 and the second actuating element BT2 to illustrate the function of the latching hook RH with its latching nose RN when pressure is applied to the control surface BF by an installer. The second actuating element BT2 is displaced from a first position S1 into a second position S2 by pressure applied to the control surface BF. The second position S2 is deep enough to ensure that the latching hook RH, with its latching nose RN, leaves the second guide element FT2, or more precisely its inner side, and passes through a recess A through a latching hole in the mounting plate MP, whereupon the elastic spring force of the latching hook RH becomes effective and the latching hook RH presses against the circuit board with a force F. When the installer releases the pressure on the control surface BF, the second actuating element BT2 slides into a locking position SV and the latching nose RN presses the module carrier BC toward the circuit board. A return element RM is disposed on a pin Z between the second actuator BT2 and the second guide element FT2. As a result, the second actuator BT2 is pressed upward when the pressure is reduced.

FIG. 5 shows a perspective view of the first actuator BT1 as a plastic injection-molded part with its corresponding latching hook RH and its latching nose RN, where the latching nose RN and the latching hook RH are elastically formed such that a force F is generated in the direction as indicated. A coil spring is provided as a return element RM inside the first actuating element BT1.

FIG. 6 again shows, in a perspective view, the arrangement of the bus connector BS in the bus connector housing BSG. The bus connector housing BSG likewise has latching hooks with latching noses, which serve to latch into corresponding latching openings in the module carrier BC, as shown in FIG. 7, viewed toward the mounting side MS.

FIG. 7 shows the module carrier BC viewed from the mounting side MS. The bus connector BS, together with its bus connector housing BSG, has already been fully displaced leftward into the module carrier BC, where the aforementioned latching hooks and latching noses from FIG. 6 are latched in a position such that the left-hand plug LBS projects out of the module carrier BC. If a further module carrier BC were now disposed at this location, then the left-hand plug LBS would latch into the corresponding right-hand plug RBS of the adjacent module carrier BC.

Finally, FIG. 8 shows the assembled electronic module EM and module carrier BC. The control surfaces BF of the actuators BT1, BT2 are provided with a structured surface. In this exemplary embodiment, the structured surface is depicted in the form of a lock symbol, which indicates that pressing it causes locking to take place.

In summary, the latching of assemblies on circuit boards presents several challenges, including tolerance compensation, functionality with different circuit board thicknesses, and the need for a manufacturing-friendly snap-fit geometry. Circuit boards typically have a tolerance of 10% of the nominal thickness dimension, which makes latching more difficult. Customer-specific requirements necessitate the use of different circuit board thicknesses.

A competitor product uses non-spring-loaded plastic latching hooks that are suitable only for 1.6 mm thick circuit boards and do not provide tolerance compensation. For thicker circuit boards, a costly depth milling operation is required.

The solution presented consists of a return element, in particular a metal spring, and a plastic part with a rounded latching hook. This construction enables the use of circuit boards having, for example, a nominal thickness of between 1.6 and 2.7 mm (±10% tolerance). The latching hook engages through a hole in the circuit board and is pressed against the rear side by the spring.

The main advantages of this solution are:
1. Complete tolerance compensation by spring mounting.
2. Play-free mounting on circuit boards of different thicknesses.
3. Constant spring force for secure fastening.
4. Flexibility in the use of different circuit board thicknesses.
5. Support for cost-effective manufacturing methods by using drilling instead of milling.

Thus, while there have been shown, described and pointed out fundamental novel features of the invention as applied to a preferred embodiment thereof, it will be understood that various omissions and substitutions and changes in the form and details of the devices illustrated, and in their operation, may be made by those skilled in the art without departing from the spirit of the invention. For example, it is expressly intended that all combinations of those elements that perform substantially the same function in substantially the same way to achieve the same results are within the scope of the invention. Moreover, it should be recognized that structures and/or elements shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

What is claimed is:

1. A modular automation system, comprising:
a circuit board;
a plurality of connection elements disposed on the circuit board;
a plurality of signal connectors disposed on the circuit board and configured to receive module connectors of an electronic module, each connection element of the plurality of elements being connected to the plurality of signal connectors via conductor tracks of the circuit board and the plurality of connection elements being configured to connect to process signal cables;
at least one module carrier into which the electronic module is inserted, the at least one module carrier having a bus connector space and a signal connector space;
a bus connector disposed in the bus connector space, the signal connector space being recessed such that, in a mounted state of the module carrier on the circuit board, a space is provided for the signal connector located on the circuit board;
wherein the bus connector space and the bus connector are configured such that the bus connector is displaceably disposed in the bus connector space, the bus connector comprising a left-hand plug, a right-hand plug, and a backplane bus plug disposed in a direction oriented toward the at least one module carrier, the backplane bus plug being configured to receive a mating module backplane bus plug of the electronic module;
wherein the at least one module carrier is configured such that the modular automation system which is modularly configurable is assembled by arranging a plurality of module carriers side-by-side; and
wherein a bus connector of a preceding module carrier is connectable to a bus connector of a succeeding module carrier by leftward displacement of the bus connector of the succeeding module carrier to form a backplane bus for the modularly configurable automation system.

2. The modular automation system as claimed in claim 1, wherein the bus connector comprises a bus circuit board including the left-hand plug, the right-hand plug (RBS), and the backplane bus plug.

3. The modular automation system as claimed in claim 1, further comprising:
a main unit; and
an adapter module disposed between the main unit and a first module carrier;
wherein the adapter module comprises an adapter circuit board upon which an adapter main unit connector and an adapter bus connector are disposed in an offset manner relative to one another.

4. The modular automation system as claimed in claim 2, further comprising:
a main unit; and
an adapter module disposed between the main unit and a first module carrier;
wherein the adapter module comprises an adapter circuit board upon which an adapter main unit connector and an adapter bus connector are disposed in an offset manner relative to one another.

5. The modular automation system as claimed in claim 3, wherein the main unit is disposed on a DIN rail.

6. The modular automation system as claimed in claim 1, further comprising:
a termination module having a termination network for the backplane bus and a memory component for node identification.

7. The modular automation system as claimed in claim 6, wherein the termination module is disposed in a termination module carrier having a termination cover.

8. The modular automation system as claimed in claim 1, wherein the module carrier comprises:
a mounting side configured to mount on the circuit board;
a left-hand side;
a right-hand side;
a receiving side for the electronic module, the receiving side being opposite the mounting side;
an upper end; and
a lower end;
wherein, for fastening to the circuit board, a first fastener is disposed in a region of the upper end and a second fastener is disposed in a region of the lower end;
wherein the fastener is configured such that an actuating element is movably disposed in a guide element, the guide element being configured such that the actuator is displaceable from the receiving side toward the mounting side by application of pressure to a control surface by an installer;
wherein the actuator includes a latching hook which is elastically deformable such that, in a first position of the actuator, a spring force of the latching hook presses a latching nose disposed at an end of the latching hook against an inner surface of the guide element;
wherein the guide element includes a recess formed in the mounting side;
wherein, in a second position of the actuator, the latching hook, with the latching nose, passes through the recess and through an opening in a mounting plate; and
wherein a return element is disposed between the mounting side, within the guide element, and the actuating element, the return element being configured to return the actuating element toward the receiving side such that the actuating element remains in a locking position and the latching nose presses against the circuit board.

9. The modular automation system as claimed in claim 1, wherein the module carrier comprises a receiver for the electronic module, the receiver comprising a first retainer and a second retainer, the first and second retainer being disposed opposite one another such that the electronic module is insertable therebetween.

10. The modular automation system as claimed in claim 1, wherein the at least one module carrier comprises a bus connector housing forming a receptacle for the bus connector, the bus connector housing being configured to latch, when displaced leftward, with a correspondingly configured bus connector space such that the left-hand plug is engaged with a right-hand plug of a bus connector of a preceding module carrier, and such that the backplane bus plug is located in a central position, so that an electronic module insertable via the receiving side is in contact with the backplane bus plug via a mating backplane bus plug.
